(19) United States
(12) Patent Application Publication
(10) Pub. No.: US 2012/0108157 A1
(43) Pub. Date: May 3, 2012

(54) CONTAINER DATA CENTER

(75) Inventor: HUNG-CHOU CHAN, Tu-Cheng (TW)

(73) Assignee: HON HAI PRECISION INDUSTRY CO., LTD., Tu-Cheng (TW)

(21) Appl. No.: 12/951,075

(22) Filed: Nov. 22, 2010

(30) Foreign Application Priority Data
Oct. 27, 2010 (TW) 99136624

(51) Int. Cl. H05K 5/00

(52) U.S. Cl. 454/184

(57) ABSTRACT

A container data center includes a portable container defining a number of inlets, a number of racks received in the container, and a number of air ducts. Each of the air ducts is mounted to the container and aligns with one corresponding inlet of the container. Each of the air ducts includes an air inlet, and an air outlet accommodated in the corresponding inlet of the container. An area of a cross section surface of the air inlet is greater than an area of a cross section of the air outlet of the air duct.

### BACKGROUND

1. Technical Field

The present disclosure relates to a container data center.

2. Description of Related Art

With increasing heavy duty use of on-line applications, the need for computer data centers has increased rapidly. Data centers are centralized computing facilities that include many servers, often arranged on server racks or shelves, and one rack or shelf with some servers can be considered a server system. During operation, server systems generate a lot of heat in the data centers, and a common method for dissipating the heat is to use cool air blown upward or downward into the data center from inlets. However, the disadvantage of this method is that the cool air cannot be efficiently scattered, which is inconvenient to dissipate the heat for the severs in the racks away from the inlets.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of an exemplary embodiment of a container data center, the container data center includes a number of air ducts.

FIG. 2 is a schematic view of an exemplary embodiment of the air duct of FIG. 1.

FIG. 3 is a schematic view of another exemplary embodiment of a container data center.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

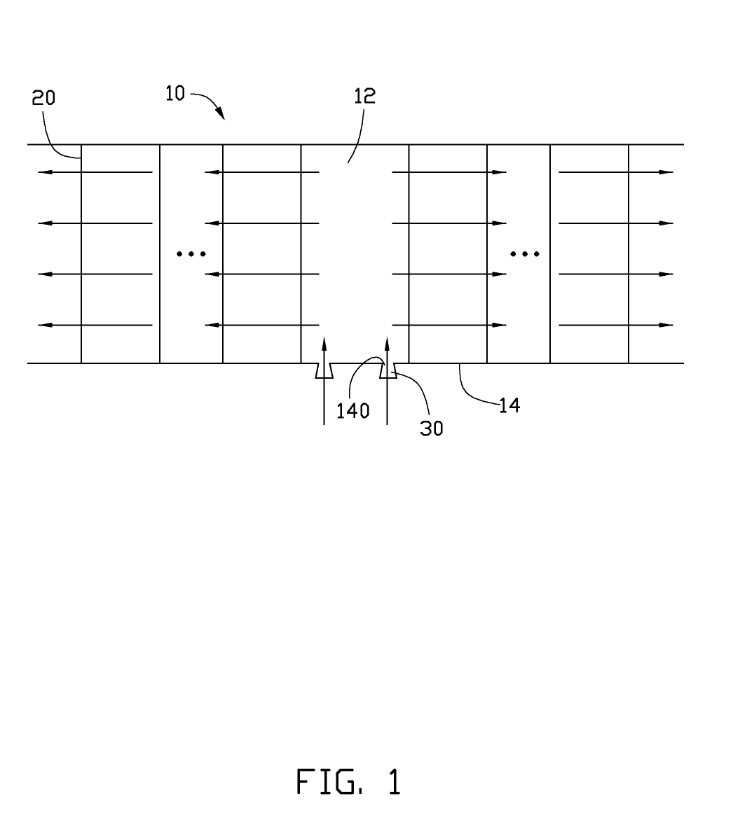

Referring to FIG. 1, a first exemplary embodiment of a container data center includes a portable container 10 and a number of racks 20 received in the container 10. The container 10 includes a top wall 12 and a bottom wall 14 opposite to the top wall 12. The bottom wall 14 defines a number of air inlets 140 arranged in two rows along a width of the container 10 and between two adjacent racks 20 in the center of the container 10. An air duct 30 is mounted to the bottom wall 14 at each air inlet 140. Guided by the air ducts 30, cold air is blown upward into the container 10 through the air inlet 140. Each rack 20 receives a number of severs (not shown). In one embodiment, the air duct 30 is hollow and tapered, with the tapered end of the air duct 30 connected to the bottom wall 14 of the container 10 and an inner space of the air duct 30 aligning and communicating with the air inlet 140.

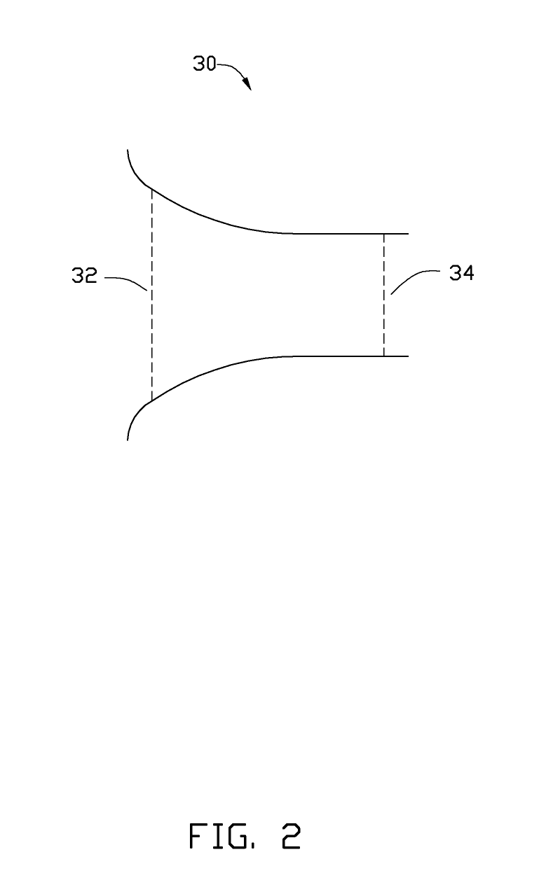

Referring to FIG. 2, in an embodiment, the air duct 30 is horn-shaped and includes a greater air inlet 32 and a smaller air outlet 34. An area of a cross section of the air inlet 32 is S1. An area of a cross section of the air outlet 34 is S2. S1 is greater than S2. The air outlet 34 is accommodated in the inlet 140 of the container 10. Hypothesizing, the speeds of cold air flowing through the air inlet 32 and air outlet 34 are respectively V1 and V2, the pressure at the air inlet 32 and air outlet 34 are respectively P1 and P2.

At the same time, the quantity of cold air flowing through the air inlet 32 is same as the quantity of cold air flowing through the air outlet 34, namely S1×V1=S2×V2. Because S1 is greater than S2, V2 is greater than V1. According to Bernoulli equation P+(½)*ρV²=C, where P stands for air pressure, ρ stands for air density, V stands for air speed, and C stands for a constant. Because V2 is greater than V1, P1 is greater than P2. Thus, a difference in pressure is formed between the air inlet 32 and the air outlet 34, which is convenient to guide and accelerate cold air to dissipate heat for the severs in the racks away from the inlets 140.

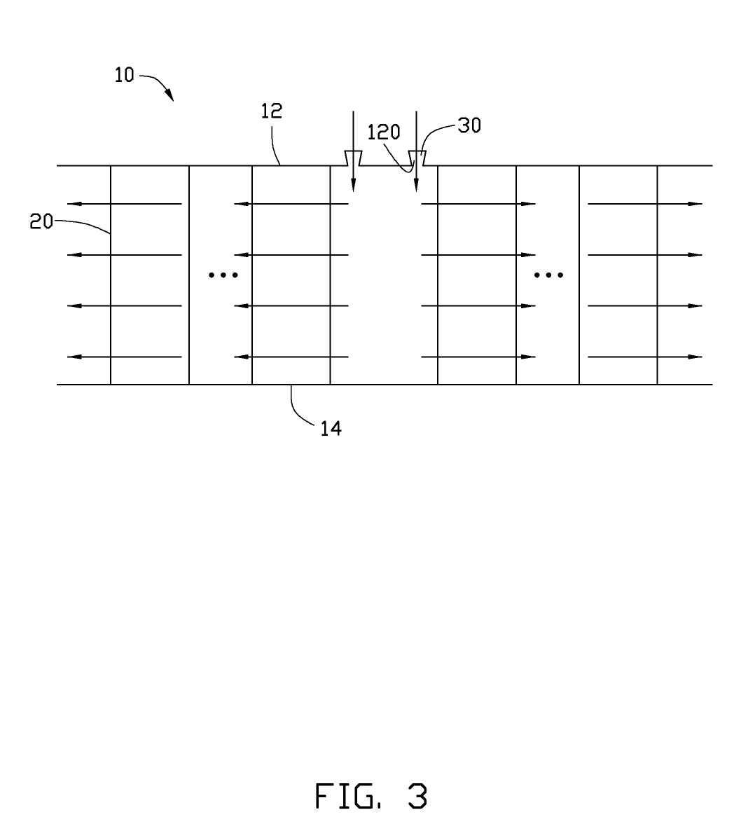

Referring to FIG. 3, a second exemplary embodiment of a container data center includes is substantially similar to the first embodiment, except that the top wall 12 defining a number of inlets 120 replaces the number of inlets 140 defined in the bottom wall 14. The cold air is blown downward into the container 10.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

1. A container data center comprising:
a portable container defining a plurality of inlets;
a plurality of racks received in the container; and
a plurality of air ducts mounted to the container and aligning with the corresponding inlets, wherein each of the plurality of air ducts comprises an air inlet, and an air outlet communicating with the corresponding inlet, an area of a cross section of the air inlet is greater than an area of a cross section of the air outlet.

2. The container data center of claim 1, wherein the container comprises a top wall, the plurality of inlets is defined in the top wall.

3. The container data center of claim 2, wherein the plurality of inlets is arranged in two rows along a width of the top wall between two adjacent racks.

4. The container data center of claim 1, wherein the container comprises a bottom wall, the plurality of inlets is defined in the top bottom.

5. The container data center of claim 4, wherein the plurality of inlets is arranged in two rows along a width of the bottom wall between two adjacent racks.

6. The container data center of claim 1, wherein each air duct is tapered, with a tapered end mounted to the container.

7. The container data center of claim 1, wherein each air duct is horn-shaped, with a smaller end mounted to the container.
